(19) United States
(12) Patent Application Publication
(10) Pub. No.: US 2017/0185292 A1
(43) Pub. Date: Jun. 29, 2017

(54) Memory Management of High-Performance Memory

(71) Applicant: Intel Corporation, Santa Clara, CA (US)

(72) Inventors: Ashish Jha, Portland, OR (US); Tulika Jha, Portland, OR (US); Mingqiu Sun, Beaverton, OR (US)

(21) Appl. No.: 14/757,418

(22) Filed: Dec. 23, 2015

(51) Int. Cl. G06F 3/06; G11C 7/10; G06F 12/02

(52) U.S. Cl. CPC G06F 3/061; G06F 12/0253; G11C 7/1072; G06F 3/0655; G06F 3/0685; G06F 2212/702

(57) ABSTRACT

Various systems and methods for memory management of high-performance memory are described herein. A system for managing high-performance memory, the system comprising a random access memory; a high-performance memory, the high-performance memory of higher performance than the random access memory; and a memory management unit to: obtain execution metrics for a plurality of blocks resident in a random access memory; select a block from the plurality of blocks based on activity of the block; move the block to high-performance memory; and update a virtual memory mapping for the block from the random access memory to the high-performance memory.

### TECHNICAL FIELD

Embodiments described herein generally relate to memory management and in particular, to memory management of high-performance memory.

### BACKGROUND

Increases in computing power is obtained by using a number of techniques including increasing central processing unit (CPU) operating speeds, increasing CPU cores, adding one or more CPU caches, adding threads per core, increasing memory bandwidth or speed, increasing the amount of primary memory, and the like.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 is a diagram illustrating an exemplary hardware and software architecture of a computer system, in which various interfaces between hardware components and software components are shown, according to an embodiment;

FIG. 2 is a block diagram illustrating control and data flow, according to an embodiment;

FIG. 3 is a block diagram illustrating a system managing high-performance memory, according to an embodiment;

FIG. 4 is a flowchart illustrating a method of managing high-performance memory, according to an embodiment; and

FIG. 5 is a block diagram illustrating an example machine upon which any one or more of the techniques (e.g., methodologies) discussed herein may perform, according to an example embodiment.

### DETAILED DESCRIPTION

In the following description, for purposes of explanation, numerous specific details are set forth in order to provide a thorough understanding of some example embodiments. It will be evident, however, to one skilled in the art that the present disclosure may be practiced without these specific details.

Conventional memory modules organize memory cells in two dimensions as rows and columns. In recent years, memory has been designed to increase the data rate (e.g., double data rate (DDR) SDRAM (synchronous dynamic random-access memory), DDR2 (type 2 DDR SDRAM), DDR3 (type 3 DDR SDRAM), etc.) or increase the bandwidth (e.g., DDR4).

New memory devices stack silicon wafers or dies and interconnect them vertically using through-silicon vias (TSVs). An example of a 3D memory module is a hybrid memory cube (HMC), which stacks individual module memory dies (e.g., memory devices) connected by internal vertical conductors, such as TSVs. TSVs are vertical conductors that electrically connect a stack of individual memory dies with a controller. The HMC may provide a smaller form factor, deliver higher bandwidth and other efficiencies while using less energy to transfer data per bit. Another example of 3D memory is high bandwidth memory (HBM), which is also designed with up to eight DRAM dies in a stacked configuration and an optional base die with a memory controller. The stack of dies in an HBM may be interconnected using TSVs. HBM provides very wide memory bandwidth when compared to conventional DRAM. For example, with four DRAM dies stacked, an HBM provides two 128-bit channels per die for a total of eight channels and a width of 1024 bits. Using four such stacks on a memory module provides a 4096-bit memory bus; a large improvement over the DDR3 or DDR4 buses. Other types of high-performance memory are also on the horizon, including 3D Xpoint™, Universal Flash Storage (UFS), 3D NAND Flash, and technologies built around Wide I/O and related standards.

Because of their high initial cost to manufacture and produce, these advanced memory modules may be provided to consumers in limited quantity. One design option is to provide high-performance memory modules along with DDR3 or DD4 SDRAM modules. Such a design offers speed increases to the end user, without full freight costs of replacing all RAM in a system with high-performance RAM.

Systems and methods described herein implement memory management of high-performance memory. Using performance metrics of an application, a memory manager may allocate hot memory blocks to high-performance memory (HPM), while leaving cold memory blocks in conventional DRAM. This memory management technique significantly improves performance across a wide range of applications from clients to enterprise. In addition, the implementations described here operate transparently for the executing applications.

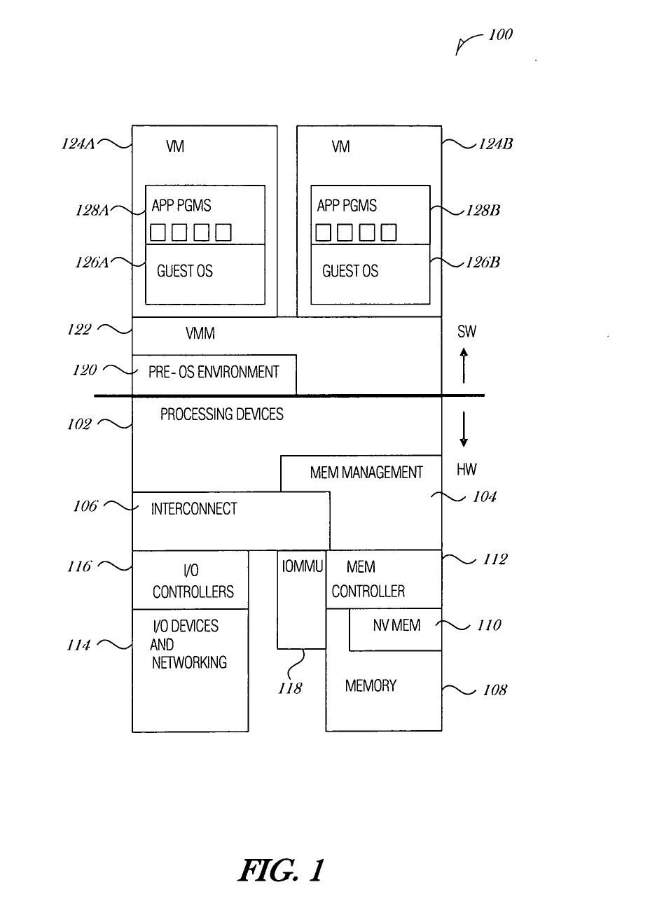

FIG. 1 is a diagram illustrating an exemplary hardware and software architecture 100 of a computer system, in which various interfaces between hardware components and software components are shown, according to an embodiment. As indicated by HW, hardware components are represented below the divider line, whereas software components denoted by SW reside above the divider line. On the hardware side, processing devices 102 (which may include one or more microprocessors, digital signal processors, etc., each having one or more processor cores, are interfaced with memory management device 104 and system interconnect 106. Memory management device 104 provides mappings between virtual memory used by processes being executed, and the physical memory. Memory management device 104 may be an integral part of a central processing unit which also includes the processing devices 102.

Interconnect 106 includes a backplane such as memory, data, and control lines, as well as the interface with input/output devices, e.g., PCI, USB, etc. Memory 108 (e.g., dynamic random access memory (DRAM)) and non-volatile memory 110 such as flash memory (e.g., electrically-erasable read-only memory—EEPROM, NAND Flash, NOR Flash, etc.) are interfaced with memory management device 104 and interconnect 106 via memory controller 112. I/O devices, including video and audio adapters, non-volatile storage, external peripheral links such as USB, Bluetooth, etc., camera/microphone data capture devices, fingerprint readers and other biometric sensors, as well as network interface devices such as those communicating via Wi-Fi or LTE-family interfaces, are collectively represented as I/O devices and networking 114, which interface with interconnect 106 via corresponding I/O controllers 116.

In a related embodiment, input/output memory management unit IOMMU 118 supports secure direct memory access (DMA) by peripherals. IOMMU 118 may provide memory protection by meditating access to memory 108 from I/O device 114. IOMMU 118 may also provide DMA memory protection in virtualized environments, where it allows certain hardware resources to be assigned to certain guest VMs running on the system, and enforces isolation between other VMs and peripherals not assigned to them.

On the software side, a pre-operating system (pre-OS) environment 120, which is executed at initial system start-up and is responsible for initiating the boot-up of the operating system. One traditional example of pre-OS environment 120 is a system basic input/output system (BIOS). In present-day systems, a unified extensible firmware interface (UEFI) is implemented. Pre-OS environment 120, described in greater detail below, is responsible for initiating the launching of the operating system or virtual machine manager, but also provides an execution environment for embedded applications according to certain aspects of the invention.

Virtual machine monitor (VMM) 122 is system software that creates and controls the execution of virtual machines (VMs) 124A and 124B. VMM318 may run directly on the hardware HW, as depicted, or VMM 122 may run under the control of an operating system as a hosted VMM.

Each VM 124A, 124B includes a guest operating system 126A, 126B, and application programs 128A, 128B.

Each guest operating system (OS) 126A, 126B provides a kernel that operates via the resources provided by VMM 122 to control the hardware devices, manage memory access for programs in memory, coordinate tasks and facilitate multi-tasking, organize data to be stored, assign memory space and other resources, load program binary code into memory, initiate execution of the corresponding application program which then interacts with the user and with hardware devices, and detect and respond to various defined interrupts. Also, each guest OS 126A, 126B provides device drivers, and a variety of common services such as those that facilitate interfacing with peripherals and networking, that provide abstraction for corresponding application programs 128A, 128B so that the applications do not need to be responsible for handling the details of such common operations. Each guest OS 126A, 126B additionally may provide a graphical user interface (GUI) that facilitates interaction with the user via peripheral devices such as a monitor, keyboard, mouse, microphone, video camera, touchscreen, and the like.

Each guest OS 126A, 126B may provide a runtime system that implements portions of an execution model, including such operations as putting parameters onto the stack before a function call, the behavior of disk input/output (I/O), and parallel execution-related behaviors.

In addition, each guest OS 126A, 126B may provide libraries that include collections of program functions that provide further abstraction for application programs. These may include shared libraries, dynamic linked libraries (DLLs), for example.

Application programs 128A, 128B are those programs that perform useful tasks for users, beyond the tasks performed by lower-level system programs that coordinate the basic operability of the computer system itself.

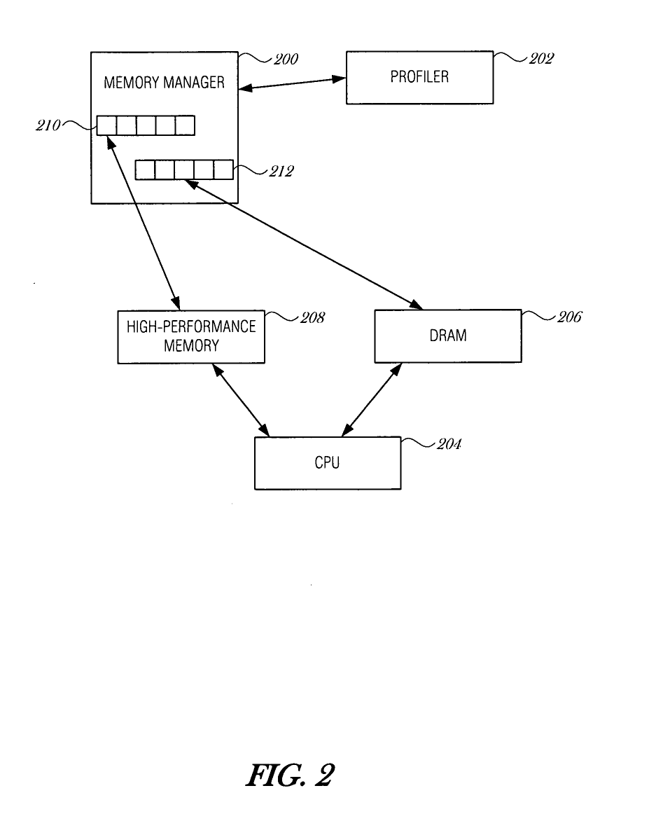

FIG. 2 is a block diagram illustrating control and data flow, according to an embodiment. A memory manager 200 interfaces with a profiler 202. The profiler 202 may be an application profiler that executes at compile time or run time. The profiler 202 may be used to identify or measure space or time complexity of a program, the usage of particular instructions or blocks of code, or the frequency or duration of function calls. The profiler 202 may use techniques such as profile guided optimization (PGO) to profile hotspots (e.g., top CPU consuming) application code blocks. In an example, the profiler 202 identifies portions of executable code that are CPU-intensive. The memory manager 200 and profiler 202 may exist in a virtual machine instance (e.g., Java Virtual Machine), an operating system component, or at the application layer (separate from a VM). An example profiler for Java applications is the Hyades Data Collection Engine for Eclipse. Another example profiler is VTune™ Amplifier XE from Intel®.

A central processing unit (CPU) 204 is coupled to a dynamic random access memory (DRAM) 206 and a high-performance memory 208. The DRAM 206 may be various types of DRAM, such as DDR2, DD3, or DD4 SDRAM. The high-performance memory 208 is of a type that is significantly higher performing than the DRAM 206. Examples of high-performance memory 208 include, but are not limited to HMC, HBM, 3D Xpoin™, Universal Flash Storage (UFS), 3D NAND Flash, and technologies built around Wide I/O and related standards.

The memory manager 200 is configured to manage the allocation of memory blocks. It maintains lists of active and free memory for each of the high-performance memory 208 and the DRAM 206. The memory manager 200 also maintains a list of hot blocks 210 and cold blocks 212, which are updated based on data from the profiler 202.

The memory manager 200 places those blocks that are profiled as being highly-active in the hot blocks list 210. These blocks are then allocated space on the high-performance memory 208. As such, a hot block is always “active.”

Cold blocks, those that are in the cold block list 212, may be purged from memory when there is no free memory in either the high-performance memory 208 or the DRAM 206.

From an initial state, the memory manager 200 may allocate memory from the DRAM 206. When a hot block is identified as being in DRAM 206, the hot block is move to high-performance memory 208. This operation may be performed during a garbage collection operation. For instance, performing the reallocation during a garbage collection compaction phase reduces overhead of memory writes, because memory blocks are already being moved in some cases during compaction.

From an executing application's perspective, the operation is seamless and transparent. The memory manager 200 handles memory access requests from the application and maps the application's address space to either the high-performance memory 208 or the DRAM 206 according to the characteristics of the memory block being written or accessed.

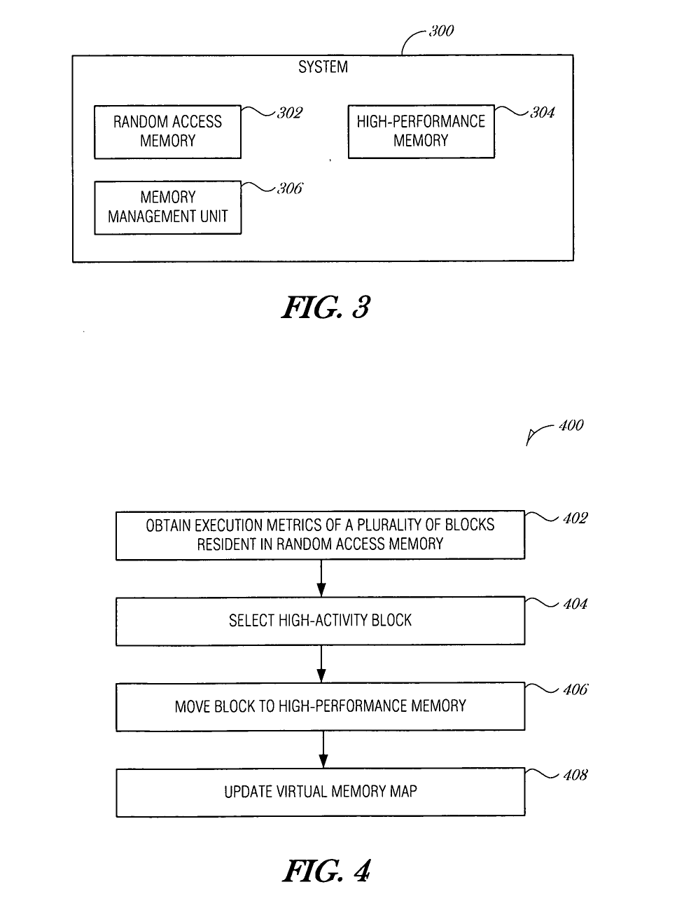

FIG. 3 is a block diagram illustrating a system 300 managing high-performance memory, according to an embodiment. The system 300 may include a random access memory 302, high-performance memory 304, and a memory management unit 306.

The random access memory 302 may include various types of DRAM, such as DDR2, DDR3, or DDR4 SDRAM. Other types of conventional memory may be used, such as SO-DIMM, SIMM, or the like.

The high-performance memory 304 is a significantly better memory than the random access memory 302. Examples of high-performance memory 304 include, but are not limited to HMC, HBM, 3D Xpoint™, Universal Flash Storage (UFS), 3D NAND Flash, and technologies built around Wide I/O) and related standards. In an embodiment, the high-performance memory 304 is high bandwidth memory (HBM) memory module. In another embodiment, the high-performance memory 304 is hybrid memory cube (HMC) memory module.

The memory management unit 306 may be configured to obtain execution metrics for a plurality of blocks resident in a random access memory 302, select a block from the plurality of blocks based on activity of the block, move the block to high-performance memory 304, and update a virtual memory mapping for the block from the random access memory 302 to the high-performance memory 304. The blocks resident in random access memory 302 and high-performance memory 304 may be maintained in cold and hot block lists, respectively, as described above with respect to FIG. 2

In an embodiment, the block is a memory frame. In a related embodiment, the metrics are accesses to the memory frame.

In an embodiment, to select the block from the plurality of blocks based on the activity of the block, the memory management unit 306 is to order blocks in the plurality of blocks by access counts and select a block with a higher access count than an unselected block. The ordered blocks may be maintained in a single list or multiple lists (e.g., hot and cold block lists).

In an embodiment, the block is a bytecode block from bytecode of an application. In a further embodiment, the bytecode block is a method of the application. In a related embodiment, the bytecode block is a data structure of the application. In a related embodiment, the bytecode block is a loop of the application.

In an embodiment, the execution metrics are obtained from a virtual machine running the application. In a further embodiment, to obtain the execution metrics, the memory management unit 306 is to invoke a profiler of the virtual machine to produce the execution metrics. In a further embodiment, the execution metrics are performance counters that count calls to the bytecode block. In yet a further embodiment, to select the block from the plurality of blocks, the memory management unit 306 is to select a block that fits into the high-performance memory 304 and has a highest performance counter metric.

In an embodiment, the operations of the memory management unit 306 are performed during a garbage collection operation. In a further embodiment, the operations of the memory management unit 306 are performed during a garbage compaction operation.

Blocks may be moved to and from high-performance memory 304 based on various factors, such as the execution metrics of additional active blocks, execution or termination of applications that allocate or deallocate memory from the high-performance memory 304 or the random access memory 302, or other circumstances that re-rank a previously “high activity” block to be a relatively “low activity” block with respect to other active blocks. As such, in an embodiment, the memory management unit 306 is to move a low-activity block from high-performance memory to random access memory and update a virtual memory mapping for the block from the high-performance memory to the random access memory.

FIG. 4 is a flowchart illustrating a method 400 of managing high-performance memory, according to an embodiment. At operation 402, execution metrics for a plurality of blocks resident in a random access memory are obtained at a memory management unit. In an embodiment, the metrics are accesses to the memory frame. In a further embodiment, selecting the block from the plurality of blocks based on the activity of the block comprises ordering blocks in the plurality of blocks by access counts and selecting a block with a higher access count than an unselected block.

At operation 404, a block is selected from the plurality of blocks based on activity of the block. In an embodiment, the block is a memory frame.

In an embodiment, the block is a bytecode block from bytecode of an application. In a further embodiment, the bytecode block is a method of the application. In a related embodiment, the bytecode block is a data structure of the application. In a related embodiment, the bytecode block is a loop of the application.

In a related embodiment, the execution metrics are obtained from a virtual machine running the application. In a further embodiment, obtaining the execution metrics comprises invoking a profiler of the virtual machine to produce the execution metrics. In a further embodiment, the execution metrics are performance counters that count calls to the bytecode block. In a related embodiment, selecting the block from the plurality of blocks comprises selecting a block that fits into the high-performance memory and has a highest performance counter metric.

At operation 406, the block is moved to high-performance memory, the high-performance memory of higher performance than the random access memory. In an embodiment, the high-performance memory is high bandwidth memory (HBM) memory module. In a related embodiment, the high-performance memory is hybrid memory cube (HMC) memory module.

At operation 408, a virtual memory mapping for the block from the random access memory to the high-performance memory is updated.

In an embodiment, the method 400 is performed during a garbage collection operation. In a further embodiment, the method 400 is performed during a garbage compaction operation.

In an embodiment, the method 400 includes moving a low-activity block from high-performance memory to random access memory and updating a virtual memory mapping for the block from the high-performance memory to the random access memory.

Embodiments may be implemented in one or a combination of hardware, firmware, and software. Embodiments may also be implemented as instructions stored on a machine-readable storage device, which may be read and executed by at least one processor to perform the operations described herein. A machine-readable storage device may include any non-transitory mechanism for storing information in a form readable by a machine (e.g., a computer). For example, a machine-readable storage device may include read-only memory (ROM), random-access memory (RAM), magnetic disk storage media, optical storage media, flash-memory devices, and other storage devices and media.

A processor subsystem may be used to execute the instruction on the machine-readable medium. The processor subsystem may include one or more processors, each with one or more cores. Additionally, the processor subsystem may be disposed on one or more physical devices. The processor subsystem may include one or more specialized processors, such as a graphics processing unit (GPU), a digital signal processor (DSP), a field programmable gate array (FPGA), or a fixed function processor.

Examples, as described herein, may include, or may operate on, logic or a number of components, modules, or mechanisms. Modules may be hardware, software, or firmware communicatively coupled to one or more processors in order to carry out the operations described herein. Modules may be hardware modules, and as such modules may be considered tangible entities capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations. Accordingly, the term hardware module is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software; the general-purpose hardware processor may be configured as respective different modules at different times. Software may accordingly configure a hardware processor, for example, to constitute a particular module at one instance of time and to constitute a different module at a different instance of time. Modules may also be software or firmware modules, which operate to perform the methodologies described herein.

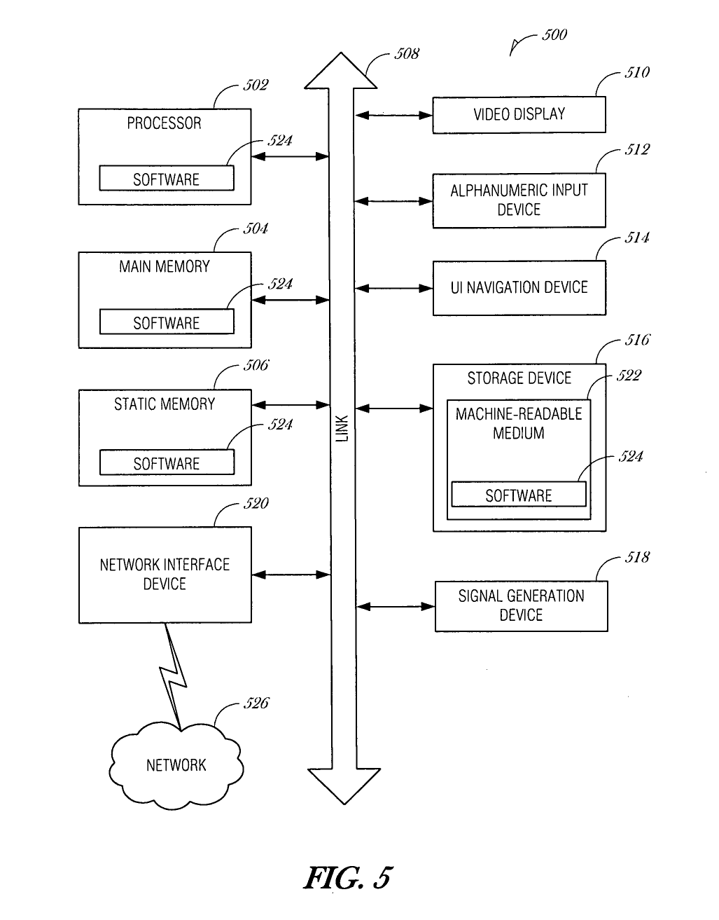

FIG. 5 is a block diagram illustrating a machine in the example form of a computer system 500, within which a set or sequence of instructions may be executed to cause the machine to perform any one of the methodologies discussed herein, according to an example embodiment. In alternative embodiments, the machine operates as a standalone device or may be connected (e.g., networked) to other machines. In a networked deployment, the machine may operate in the capacity of either a server or a client machine in server-client network environments, or it may act as a peer machine in peer-to-peer (or distributed) network environments. The machine may be an onboard vehicle system, wearable device, personal computer (PC), a tablet PC, a hybrid tablet, a personal digital assistant (PDA), a mobile telephone, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein. Similarly, the term “processor-based system” shall be taken to include any set of one or more machines that are controlled by or operated by a processor (e.g., a computer) to individually or jointly execute instructions to perform any one or more of the methodologies discussed herein.

Example computer system 500 includes at least one processor 502 (e.g., a central processing unit (CPU), a graphics processing unit (GPU) or both, processor cores, compute nodes, etc.), a main memory 504 and a static memory 506, which communicate with each other via a link 508 (e.g., bus). The computer system 500 may further include a video display unit 510, an alphanumeric input device 512 (e.g., a keyboard), and a user interface (UI) navigation device 514 (e.g., a mouse). In one embodiment, the video display unit 510, input device 512 and UI navigation device 514 are incorporated into a touch screen display. The computer system 500 may additionally include a storage device 516 (e.g., a drive unit), a signal generation device 518 (e.g., a speaker), a network interface device 520, and one or more sensors (not shown), such as a global positioning system (GPS) sensor, compass, accelerometer, gyrometer, magnetometer, or other sensor.

The storage device 516 includes a machine-readable medium 522 on which is stored one or more sets of data structures and instructions 524 (e.g., software) embodying or utilized by any one or more of the methodologies or functions described herein. The instructions 524 may also reside, completely or at least partially, within the main memory 504, static memory 506, and/or within the processor 502 during execution thereof by the computer system 500, with the main memory 504, static memory 506, and the processor 502 also constituting machine-readable media.

While the machine-readable medium 522 is illustrated in an example embodiment to be a single medium, the term “machine-readable medium” may include a single medium or multiple media (e.g., a centralized or distributed database, and/or associated caches and servers) that store the one or more instructions 524. The term “machine-readable medium” shall also be taken to include any tangible medium that is capable of storing, encoding or carrying instructions for execution by the machine and that cause the machine to perform any one or more of the methodologies of the present disclosure or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks.

The instructions 524 may further be transmitted or received over a communications network 526 using a transmission medium via the network interface device 520 utilizing any one of a number of well-known transfer protocols (e.g., HTTP). Examples of communication networks include a local area network (LAN), a wide area network (WAN), the Internet, mobile telephone networks, plain old telephone (POTS) networks, and wireless data networks (e.g., Bluetooth, Wi-Fi, 3G, and 4G LTE/LTE-A or WiMAX networks). The term “transmission medium” shall be taken to include any intangible medium that is capable of storing, encoding, or carrying instructions for execution by the machine, and includes digital or analog communications signals or other intangible medium to facilitate communication of such software.

### ADDITIONAL NOTES & EXAMPLES:

Example 1 includes subject matter (such as a device, apparatus, or machine) for managing high-performance memory comprising: a random access memory; a high-performance memory, the high-performance memory of higher performance than the random access memory; and a memory management unit to: obtain execution metrics for a plurality of blocks resident in a random access memory; select a block from the plurality of blocks based on activity of the block; move the block to high-performance memory; and update a virtual memory mapping for the block from the random access memory to the high-performance memory.

In Example 2, the subject matter of Example 1 may include, wherein the block is a memory frame.

In Example 3, the subject matter of any one of Examples 1 to 2 may include, wherein the metrics are accesses to the memory frame.

In Example 4, the subject matter of any one of Examples 1 to 3 may include, wherein to select the block from the plurality of blocks based on the activity of the block, the memory management unit is to: order blocks in the plurality of blocks by access counts; and select a block with a higher access count than an unselected block.

In Example 5, the subject matter of any one of Examples 1 to 4 may include, wherein the block is a bytecode block from bytecode of an application.

In Example 6, the subject matter of any one of Examples 1 to 5 may include, wherein the bytecode block is a method of the application.

In Example 7, the subject matter of any one of Examples 1 to 6 may include, wherein the bytecode block is a data structure of the application.

In Example 8, the subject matter of any one of Examples 1 to 7 may include, wherein the bytecode block is a loop of the application.

In Example 9, the subject matter of any one of Examples 1 to 8 may include, wherein the execution metrics are obtained from a virtual machine running the application.

In Example 10, the subject matter of any one of Examples 1 to 9 may include, wherein to obtain the execution metrics, the memory management unit is to invoke a profiler of the virtual machine to produce the execution metrics.

In Example 11, the subject matter of any one of Examples 1 to 10 may include, wherein the execution metrics are performance counters that count calls to the bytecode block.

In Example 12, the subject matter of any one of Examples 1 to 11 may include, wherein to select the block from the plurality of blocks, the memory management unit is to select a block that fits into the high-performance memory and has a highest performance counter metric.

In Example 13, the subject matter of any one of Examples 1 to 12 may include, wherein the high-performance memory is high bandwidth memory (HBM) memory module.

In Example 14, the subject matter of any one of Examples 1 to 13 may include, wherein the high-performance memory is hybrid memory cube (HMC) memory module.

In Example 15, the subject matter of any one of Examples 1 to 14 may include, wherein the operations of the memory management unit are performed during a garbage collection operation.

In Example 16, the subject matter of any one of Examples 1 to 15 may include, wherein the operations of the memory management unit are performed during a garbage compaction operation.

In Example 17, the subject matter of any one of Examples 1 to 16 may include, wherein the memory management unit is to: move a low-activity block from high-performance memory to random access memory; and update a virtual memory mapping for the block from the high-performance memory to the random access memory.

Example 18 includes subject matter (such as a method, means for performing acts, machine readable medium including instructions that when performed by a machine cause the machine to performs acts, or an apparatus to perform) for managing high-performance memory comprising: obtaining, at a memory management unit, execution metrics for a plurality of blocks resident in a random access memory; selecting a block from the plurality of blocks based on activity of the block; moving the block to high-performance memory, the high-performance memory of higher performance than the random access memory; and updating a virtual memory mapping for the block from the random access memory to the high-performance memory.

In Example 19, the subject matter of Example 18 may include, wherein the block is a memory frame.

In Example 20, the subject matter of any one of Examples 18 to 19 may include, wherein the metrics are accesses to the memory frame.

In Example 21, the subject matter of any one of Examples 18 to 20 may include, wherein selecting the block from the plurality of blocks based on the activity of the block comprises: ordering blocks in the plurality of blocks by access counts; and selecting a block with a higher access count than an unselected block.

In Example 22, the subject matter of any one of Examples 18 to 21 may include, wherein the block is a bytecode block from bytecode of an application.

In Example 23, the subject matter of any one of Examples 18 to 22 may include, wherein the bytecode block is a method of the application.

In Example 24, the subject matter of any one of Examples 18 to 23 may include, wherein the bytecode block is a data structure of the application.

In Example 25, the subject matter of any one of Examples 18 to 24 may include, wherein the bytecode block is a loop of the application.

In Example 26, the subject matter of any one of Examples 18 to 25 may include, wherein the execution metrics are obtained from a virtual machine running the application.

In Example 27, the subject matter of any one of Examples 18 to 26 may include, wherein obtaining the execution metrics comprises invoking a profiler of the virtual machine to produce the execution metrics.

In Example 28, the subject matter of any one of Examples 18 to 27 may include, wherein the execution metrics are performance counters that count calls to the bytecode block.

In Example 29, the subject matter of any one of Examples 18 to 28 may include, wherein selecting the block from the plurality of blocks comprises selecting a block that fits into the high-performance memory and has a highest performance counter metric.

In Example 30, the subject matter of any one of Examples 18 to 29 may include, wherein the high-performance memory is high bandwidth memory (HBM) memory module.

In Example 31, the subject matter of any one of Examples 18 to 30 may include, wherein the high-performance memory is hybrid memory cube (HMC) memory module.

In Example 32, the subject matter of any one of Examples 18 to 31 may include, wherein the method is performed during a garbage collection operation.

In Example 33, the subject matter of any one of Examples 18 to 32 may include, wherein the method is performed during a garbage compaction operation.

In Example 34, the subject matter of any one of Examples 18 to 33 may include, moving a low-activity block from high-performance memory to random access memory; and updating a virtual memory mapping for the block from the high-performance memory to the random access memory.

Example 35 includes at least one machine-readable medium including instructions, which when executed by a machine, cause the machine to perform operations of any of the Examples 18-34.

Example 36 includes an apparatus comprising means for performing any of the Examples 18-34.

Example 37 includes subject matter (such as a device, apparatus, or machine) for managing high-performance memory comprising: means for obtaining, at a memory management unit, execution metrics for a plurality of blocks resident in a random access memory; means for selecting a block from the plurality of blocks based on activity of the block; means for moving the block to high-performance memory, the high-performance memory of higher performance than the random access memory; and means for updating a virtual memory mapping for the block from the random access memory to the high-performance memory.

In Example 38, the subject matter of Example 37 may include, wherein the block is a memory frame.

In Example 39, the subject matter of any one of Examples 37 to 38 may include, wherein the metrics are accesses to the memory frame.

In Example 40, the subject matter of any one of Examples 37 to 39 may include, wherein the means for selecting the block from the plurality of blocks based on the activity of the block comprise: means for ordering blocks in the plurality of blocks by access counts; and means for selecting a block with a higher access count than an unselected block.

In Example 41, the subject matter of any one of Examples 37 to 40 may include, wherein the block is a bytecode block from bytecode of an application.

In Example 42, the subject matter of any one of Examples 37 to 41 may include, wherein the bytecode block is a method of the application.

In Example 43, the subject matter of any one of Examples 37 to 42 may include, wherein the bytecode block is a data structure of the application.

In Example 44, the subject matter of any one of Examples 37 to 43 may include, wherein the bytecode block is a loop of the application.

In Example 45, the subject matter of any one of Examples 37 to 44 may include, wherein the execution metrics are obtained from a virtual machine running the application.

In Example 46, the subject matter of any one of Examples 37 to 45 may include, wherein the means for obtaining the execution metrics comprise means for invoking a profiler of the virtual machine to produce the execution metrics.

In Example 47, the subject matter of any one of Examples 37 to 46 may include, wherein the execution metrics are performance counters that count calls to the bytecode block.

In Example 48, the subject matter of any one of Examples 37 to 47 may include, wherein the means for selecting the block from the plurality of blocks comprise means for selecting a block that fits into the high-performance memory and has a highest performance counter metric.

In Example 49, the subject matter of any one of Examples 37 to 48 may include, wherein the high-performance memory is high bandwidth memory (HBM) memory module.

In Example 50, the subject matter of any one of Examples 37 to 49 may include, wherein the high-performance memory is hybrid memory cube (HMC) memory module.

In Example 51, the subject matter of any one of Examples 37 to 50 may include, wherein the operations of claim 37 are performed during a garbage collection operation.

In Example 52, the subject matter of any one of Examples 37 to 51 may include, wherein the operations of claim 37 are performed during a garbage compaction operation.

In Example 53, the subject matter of any one of Examples 37 to 52 may include, means for moving a low-activity block from high-performance memory to random access memory; and means for updating a virtual memory mapping for the block from the high-performance memory to the random access memory.

Example 54 includes subject matter (such as a device, apparatus, or machine) for managing high-performance memory comprising: a processor subsystem; and a memory including instructions, which when executed by the processor subsystem, cause the processor subsystem to: obtain, at a memory management unit, execution metrics for a plurality of blocks resident in a random access memory; select a block from the plurality of blocks based on activity of the block; move the block to high-performance memory, the high-performance memory of higher performance than the random access memory; and update a virtual memory mapping for the block from the random access memory to the high-performance memory.

In Example 55, the subject matter of Example 54 may include, wherein the block is a memory frame.

In Example 56, the subject matter of any one of Examples 54 to 55 may include, wherein the metrics are accesses to the memory frame.

In Example 57, the subject matter of any one of Examples 54 to 56 may include, wherein the instructions to select the block from the plurality of blocks based on the activity of the block comprise instructions to: order blocks in the plurality of blocks by access counts; and select a block with a higher access count than an unselected block.

In Example 58, the subject matter of any one of Examples 54 to 57 may include, wherein the block is a bytecode block from bytecode of an application.

In Example 59, the subject matter of any one of Examples 54 to 58 may include, wherein the bytecode block is a method of the application.

In Example 60, the subject matter of any one of Examples 54 to 59 may include, wherein the bytecode block is a data structure of the application.

In Example 61, the subject matter of any one of Examples 54 to 60 may include, wherein the bytecode block is a loop of the application.

In Example 62, the subject matter of any one of Examples 54 to 61 may include, wherein the execution metrics are obtained from a virtual machine running the application.

In Example 63, the subject matter of any one of Examples 54 to 62 may include, wherein the instructions to obtain the execution metrics comprise instructions to invoke a profiler of the virtual machine to produce the execution metrics.

In Example 64, the subject matter of any one of Examples 54 to 63 may include, wherein the execution metrics are performance counters that count calls to the bytecode block.

In Example 65, the subject matter of any one of Examples 54 to 64 may include, wherein the instructions to select the block from the plurality of blocks comprise instructions to select a block that fits into the high-performance memory and has a highest performance counter metric.

In Example 66, the subject matter of any one of Examples 54 to 65 may include, wherein the high-performance memory is high bandwidth memory (HBM) memory module.

In Example 67, the subject matter of any one of Examples 54 to 66 may include, wherein the high-performance memory is hybrid memory cube (HMC) memory module.

In Example 68, the subject matter of any one of Examples 54 to 67 may include, wherein the instructions of claim 54 are performed during a garbage collection operation.

In Example 69, the subject matter of any one of Examples 54 to 68 may include, wherein the instructions of claim 54 are performed during a garbage compaction operation.

In Example 70, the subject matter of any one of Examples 54 to 69 may include, instructions to: move a low-activity block from high-performance memory to random access memory; and update a virtual memory mapping for the block from the high-performance memory to the random access memory.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

What is claimed is:

1. A system for managing high-performance memory, the system comprising:
a random access memory;
a high-performance memory, the high-performance memory of higher performance than the random access memory; and
a memory management unit to:
obtain execution metrics for a plurality of blocks resident in a random access memory;
select a block from the plurality of blocks based on activity of the block;
move the block to high-performance memory; and
update a virtual memory mapping for the block from the random access memory to the high-performance memory.

2. The system of claim 1, wherein the block is a memory frame.

3. The system of claim 2, wherein the metrics are accesses to the memory frame.

4. The system of claim 3, wherein to select the block from the plurality of blocks based on the activity of the block, the memory management unit is to:
order blocks in the plurality of blocks by access counts; and
select a block with a higher access count than an unselected block.

5. The system of claim 1, wherein the block is a bytecode block from bytecode of an application.

6. The system of claim 5, wherein the bytecode block is a method of the application.

7. The system of claim 5, wherein the bytecode block is a data structure of the application.

8. The system of claim 5, wherein the bytecode block is a loop of the application.

9. The system of claim 5, wherein the execution metrics are obtained from a virtual machine running the application.

10. The system of claim 9, wherein to obtain the execution metrics, the memory management unit is to invoke a profiler of the virtual machine to produce the execution metrics.

11. The system of claim 10, wherein the execution metrics are performance counters that count calls to the bytecode block.

12. The system of claim 11, wherein to select the block from the plurality of blocks, the memory management unit is to select a block that fits into the high-performance memory and has a highest performance counter metric.

13. The system of claim 1, wherein the high-performance memory is high bandwidth memory (HBM) memory module.

14. The system of claim 1, wherein the high-performance memory is hybrid memory cube (HMC) memory module.

15. The system of claim 1, wherein the operations of the memory management unit are performed during a garbage collection operation.

16. The system of claim 15, wherein the operations of the memory management unit are performed during a garbage compaction operation.

17. The system of claim 1, wherein the memory management unit is to:
move a low-activity block from high-performance memory to random access memory; and
update a virtual memory mapping for the block from the high-performance memory to the random access memory.

18. A method of managing high-performance memory, the method comprising:
obtaining, at a memory management unit, execution metrics for a plurality of blocks resident in a random access memory;
selecting a block from the plurality of blocks based on activity of the block;
moving the block to high-performance memory, the high-performance memory of higher performance than the random access memory; and
updating a virtual memory mapping for the block from the random access memory to the high-performance memory.

19. The method of claim 18, wherein the block is a bytecode block from bytecode of an application.

20. The method of claim 19, wherein the bytecode block is a method of the application.

21. The method of claim 19, wherein the execution metrics are obtained from a virtual machine running the application.

22. The method of claim 21, wherein obtaining the execution metrics comprises invoking a profiler of the virtual machine to produce the execution metrics.

23. At least one machine-readable medium including instructions, which when executed by a machine, cause the machine to:
obtain execution metrics for a plurality of blocks resident in a random access memory;
select a block from the plurality of blocks based on activity of the block;
move the block to high-performance memory; and
update a virtual memory mapping for the block from the random access memory to the high-performance memory.

24. The at least one machine-readable medium of claim 23, wherein the high-performance memory is high bandwidth memory (HBM) memory module.

25. The at least one machine-readable medium of claim 23, wherein the instructions are performed during a garbage collection operation.
